(19) United States
(12) Patent Application Publication
(10) Pub. No.: US 2011/0272707 A1
(43) Pub. Date: Nov. 10, 2011

(54) SUBSTRATES AND METHODS OF FORMING FILM STRUCTURES TO FACILITATE SILICON CARBIDE EPITAXY

(75) Inventors: Sima Dimitrijev, Shailer Park (AU); Li Wang, Berrinba (AU); Jisheng Han, Calamvale (AU); Alan Iacopi, Thornlands (AU); Herbert Barry Harrison, Caloundra (AU)

(73) Assignee: Qs Semiconductor Australia Pty Ltd, East Melbourne (AU)

(21) Appl. No.: 12/775,419

(22) Filed: May 6, 2010

(51) Int. Cl. H01L 29/24; H01L 21/20

(52) U.S. Cl. 257/77; 438/478; 257/E21.09; 257/E29.104

(57) ABSTRACT

Embodiments of the invention relate generally to semiconductors and semiconductor fabrication techniques, and more particularly, to devices, integrated circuits, substrates, wafers and methods to form film structures to facilitate formation of silicon carbide epitaxy on a substrate, such as a silicon-based substrate. In some embodiments, a method of preparing a substrate for silicon carbide epitaxial layer formation can include forming an ultrathin layer of oxide that is configured to inhibit contaminants from interacting with a silicon-based substrate. Further, the method can include forming a carbonized film on the silicon-based substrate that is configured to inhibit contaminants from interacting with the silicon-based substrate. The carbonized film can be configured to be transitory as fabrication parameters are modified to form an epitaxial layer of silicon carbide.

### CROSS-REFERENCE TO RELATED APPLICATIONS

This application is related U.S. patent application Ser. No. 12/543,473, filed Aug. 18, 2009 with Attorney Docket No. QS S-005 and titled “Substrates and Methods of Fabricating Epitaxial Silicon Carbide Structures with Sequential Emphasis,” and U.S. patent application Ser. No. 12/543,478, filed Aug. 18, 2009 with Attorney Docket No. QSS-006 and titled “Substrates and Methods of Fabricating Doped Epitaxial Silicon Carbide Structures with Sequential Emphasis,” each of which is herein incorporated by reference for all purposes.

### FIELD

Embodiments of the invention relate generally to semiconductors and semiconductor fabrication techniques, and more particularly, to devices, integrated circuits, substrates, wafers and methods to form film structures to facilitate formation of silicon carbide epitaxy on a substrate, such as a silicon-based substrate.

### BACKGROUND

A variety of conventional memory cells structures have been developed in various memory technologies. Silicon carbide has been identified recently as a material that can be used to manufacture structures that can retain data in a non-volatile manner. While silicon carbide and methods of fabricating the same have been used to fabricate conventional semiconductor devices, such as light emitting devices (“LEDs”) devices and high power switching devices, traditional techniques for fabricating silicon carbide semiconductors may not be well-suited for manufacturing non-volatile memory devices. While functional, some conventional approaches use sources of silicon or carbon that include other elements, such as hydrogen, that might contribute to formation of undesirable structures when forming a silicon carbide epitaxial layer on or over a substrate, such as a silicon substrate. The locations of such undesirable structures or defects are typically at or near the interface between the silicon substrate and the silicon carbide layer.

In some conventional approaches of fabricating silicon carbide structures, oxygen and/or carbon contamination may influence the formation of undesirable structures. Carbon contaminants might also affect the formation of the silicon carbide epitaxial layers when uncontrolled carbon diffuses into the silicon substrate and/or distorts the silicon lattice structure of the substrate. In some cases, a source of carbon contamination might be the internal surfaces of, for example, an epitaxial reactor. The presence of uncontrolled oxygen can contribute to formation of silicon dioxide (“SiO₂”), which may interfere with reactions between a silicon substrate and a reacting gas or precursor. SiO₂ also might contribute to other defects (e.g., stacking faults) in one or more silicon carbide epitaxial layers. Therefore, common fabrication techniques performed prior to formation of the silicon carbide typically aim to exclude or minimize the inadvertent use of either oxygen to avoid growth of SiO₂ or carbon, or both.

Usually during conventional approaches of fabricating silicon carbide structures, the surface of a semiconductor substrate or wafer generally is processed prior to silicon carbide formation in an attempt to decrease the effects of contamination, including the removal of native oxide. The native oxide obscures the crystal pattern of the semiconductor substrate, and interferes with the growth of silicon carbide epitaxial layer and its orientation with the semiconductor substrate. Hydrogen annealing and vacuum annealing techniques, for example, have been used to remove a native oxide grown on the semiconductor wafer. A native oxide is usually formed on a silicon surface when exposed to an ambient environment that includes air. A drawback to these techniques is that they tend to remove oxide non-uniformly, which, in turn, might expose portions of the semiconductor surface, which can contribute to the roughness of the surface. Another drawback is that these techniques are performed generally at relatively high temperatures that are sufficient, for instance, to cause carbon to interact via exposed localized portions with the semiconductor substrate. Such diffusion can cause etch pits and crystal lattice distortion.

It is desirable to provide improved techniques, systems, integrated circuits, wafers, and methods that minimize one or more of the drawbacks associated with devices, integrated circuits, substrates, wafers and methods for forming film structures to facilitate silicon carbide formation.

### BRIEF DESCRIPTION OF THE DRAWINGS

The invention and its various embodiments are more fully appreciated in connection with the following detailed description taken in conjunction with the accompanying drawings, in which:

FIG. 1 is a diagram depicting an example of a flow to prepare a substrate surface for silicon carbide formation, according to various embodiments;

FIG. 2 is a flow diagram depicting an example of a process for preparing a surface of a substrate to facilitate silicon carbide deposition, according to at least some embodiments;

FIG. 3 is a flow diagram depicting an example of activating a substrate surface for silicon carbide deposition, according to various embodiments;

FIG. 4 is a diagram depicting an example of introducing materials during the formation of an ultrathin oxide and the activation of substrate surface, according to various embodiments;

FIG. 5 is a flow diagram depicting an example of forming an ultrathin carbonized film, according to various embodiments;

FIG. 6 is a diagram depicting an example of introducing materials during the formation of an ultrathin carbonized film, according to various embodiments;

FIG. 7 illustrates a system implementing a process controller that is configured to form an ultrathin oxide, activate a substrate surface, and/or form an ultrathin carbonized film, according to some embodiments; and

FIG. 8 illustrates an exemplary computer system suitable to form an ultrathin oxide, activate a substrate surface, and/or form an ultrathin carbonized film, according to at least one embodiment.

Like reference numerals refer to corresponding parts throughout the several views of the drawings. Note that most of the reference numerals include one or two left-most digits that generally identify the figure that first introduces that reference number.

### DETAILED DESCRIPTION

Various embodiments or examples of the invention may be implemented in numerous ways, including as a system, a process, an apparatus, or a series of program instructions on a computer readable medium such as a computer readable storage medium or a computer network where the program instructions are sent over optical, electronic, or wireless communication links. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims, and numerous alternatives, modifications, and equivalents are encompassed. Numerous specific details are set forth in the following description in order to provide a thorough understanding. These details are provided as examples and the described techniques may be practiced according to the claims without some or all of the accompanying details. For clarity, technical material that is known in the technical fields related to the examples has not been described in detail to avoid unnecessarily obscuring the description.

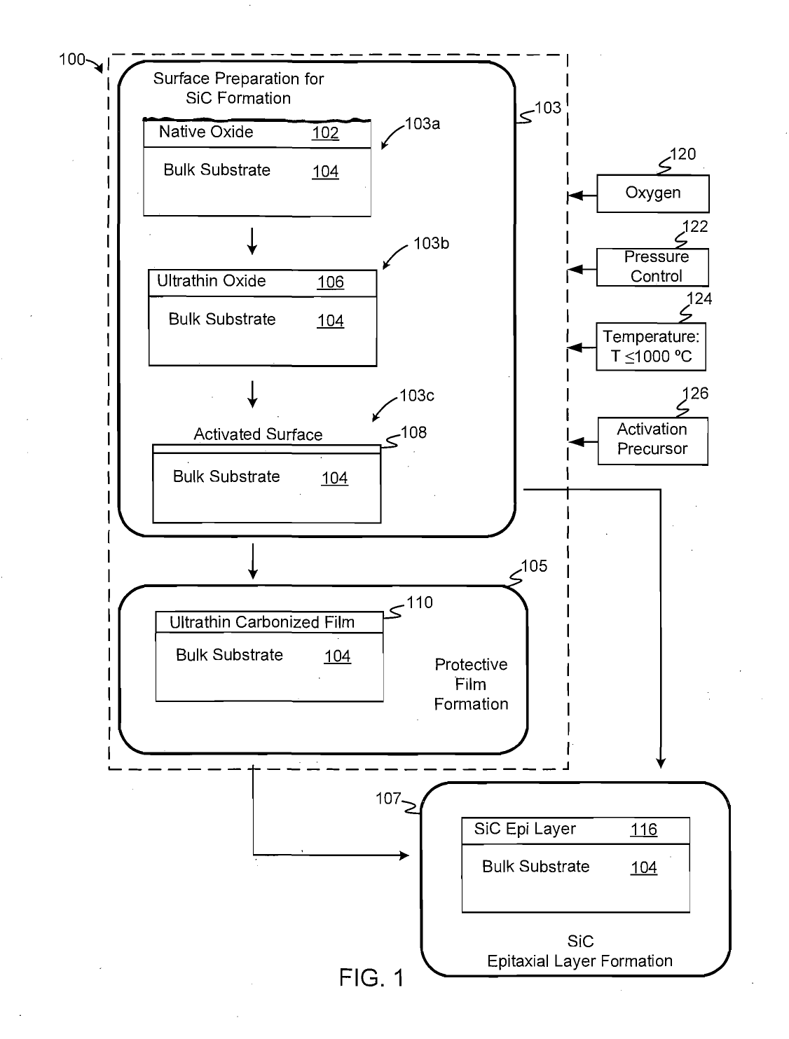

FIG. 1 is a diagram depicting an example of a flow to prepare a substrate surface for silicon carbide formation, according to various embodiments. Flow 100 can include one or more sub-processes to adapt a substrate (e.g., the substrate surface) to facilitate silicon carbide (“SiC”) epitaxial layer formation. Flow 100 is shown to include sub-process 103 for preparing a substrate surface for silicon carbide epitaxial layer formation, sub-process 105 for forming a protective layer (e.g., a transitory film) during transitions of fabrication parameters, and sub-process 107 for forming a silicon carbide epitaxial layer. Sub-processes 103 is shown to be influenced by various fabrication parameters, which, for example, can include an introduction of oxygen 120, a pressure 122 that can be controlled over a range of pressures, a temperature 124 that can be controlled over a range of temperatures, and an introduction of an activation precursor 126 (i.e., a precursor or material). An example of activation precursor 126 is silicon (e.g., in a gaseous form). Sub-process 103 is configured to activate the surface of a bulk substrate 104. In particular, bulk substrate 104, which has a native oxide 102 grown thereupon, is introduced at 103a into sub-process 103. At 103b, an ultrathin oxide 106 is grown on bulk substrate 104 for a first set of fabrication parameters, and can be transitory in nature. In some cases, ultrathin oxide 106 can be described as a film. Ultrathin layer of oxide 106 is configured to inhibit contaminants from interacting with bulk substrate 104. At 103c, flow 100 implements a second set of fabrication parameters to activate the surface of bulk substrate 104 to form an activation surface 108. Once the surface is activated, flow 100 can continue to either sub-process 105 or sub-process 107. In sub-process 105, an ultrathin carbonized film 110 is formed on bulk substrate 104 that is configured to inhibit contaminants from interacting with bulk substrate 104 as fabrication parameters are modified (e.g., to form an epitaxial layer 116 of silicon carbide). In sub-process 107, a silicon carbide epitaxial layer 116 is formed either using ultrathin carbonized film 110 (i.e., flow 100 moves from sub-process 105 to sub-process 107) or without using ultrathin carbonized film (i.e., flow 100 moves from sub-process 103 to sub-process 107). Silicon carbide epitaxial layer 116 can include silicon carbide of the form 3C—SiC, as well as any other form or polytype, according to various embodiments.

In view of the foregoing, the processes of activating the surface of bulk substrate 104 and/or forming a protective film (i.e., ultrathin carbonized film 110) can enhance the structures and/or functionalities of a wafer (i.e., a base wafer) and subsequent circuitry formed in silicon carbide that is formed upon the wafer. In at least some embodiments, oxygen 120 is used deliberately to form a SiO₂ layer, such as ultrathin oxide 106, which is configured to inhibit uncontrolled interactions of contaminants (e.g., carbon) with bulk substrate 104. In some examples, bulk substrate 104 is a silicon substrate. Therefore, as a fabrication parameters changes (i.e., is modified), such as an increase in temperature, the formation of ultrathin oxide 106 can inhibit and/or reduce the interactions of carbon and silicon (e.g., partially-activated silicon) that otherwise may give rise to undesirable structures (e.g., etch pits, deformations in the silicon lattice, etc.). Ultrathin oxide 106 also can reduce or eliminate a need to clean a chamber (e.g., a tube in an epitaxial reactor) that otherwise might be a source of carbon contaminants from previous silicon carbide deposition cycles. Also, the deliberate formation of a SiO₂ layer (e.g., ultrathin oxide 106) provides for a uniform (or a generally more uniform) than native oxide 102. A more uniform layer of ultrathin oxide 106 facilitates the uniform removal of the SiO₂ at 103c, which, in turn, reduces or eliminates localized exposure to the silicon substrate that otherwise interacts with carbon. Uniform removal of the SiO₂ also can provide for a more uniform or a smoother silicon surface, as well as a more uniform or smooth interface of silicon-silicon carbide. A smoother interface can minimize or eliminate defects in a silicon carbide layer that otherwise might cause leakage in semiconductor devices and circuitry formed in the silicon carbide layer.

In some embodiments, activating the surface of bulk substrate 104 can include removing ultrathin oxide 106 (and native oxide 102 over which ultrathin oxide 106 can be formed) in a uniform manner. In some examples, activation precursor 126 can include a silicon-based gas to remove ultrathin oxide 106. Further, the removal of ultrathin oxide 106 can also provide for the removal of impurities in the ultrathin oxide 106, thereby cleaning the wafer and its surface. As such, sub-process 103 can obviate a need to clean (e.g., mechanically or chemically) the surface of a wafer prior to silicon carbide formation. In at least some embodiments, ultrathin carbonized film 110 is formed below a surface activation temperature to inhibit interactions between carbon and silicon. Ultrathin carbonized film 110 can be a relatively thin (e.g., one or more monolayers of silicon carbide). In some examples, ultrathin carbonized film 110 can be composed of a monolayer of silicon carbide. Further, ultrathin carbonized film 110 can be composed of multiple monolayers of silicon carbide. For example, ultrathin carbonized film 110 can be composed of several monolayers of silicon carbide (e.g., three or more monolayers). Therefore, ultrathin carbonized film 110 can be sufficiently sized to reduce or eliminate silicon outdiffusion from, and carbon diffusion into, bulk substrate 104, and also can be sufficiently sized to minimize delays in the formation of a silicon carbide epitaxial layer 116 in sub-process 107. Ultrathin carbonized film 110 can be less than 7 nm, or less, according to some embodiments. Ultrathin carbonized film 110 can be dissolved, at in some cases, relatively quickly due to its thickness, which can range from a monolayer to a thickness greater than a monolayer. In at least some embodiments, oxygen 120 is used deliberately to form a SiO₂ layer, such as ultrathin oxide 106, which is configured to inhibit uncontrolled interactions of contaminants (e.g., carbon) with bulk substrate 104. In some embodiments, flow 100 can be implemented using low pressure chemical vapor deposition (“LPCVD”) rather than using molecular beam epitaxy (“MBE”).

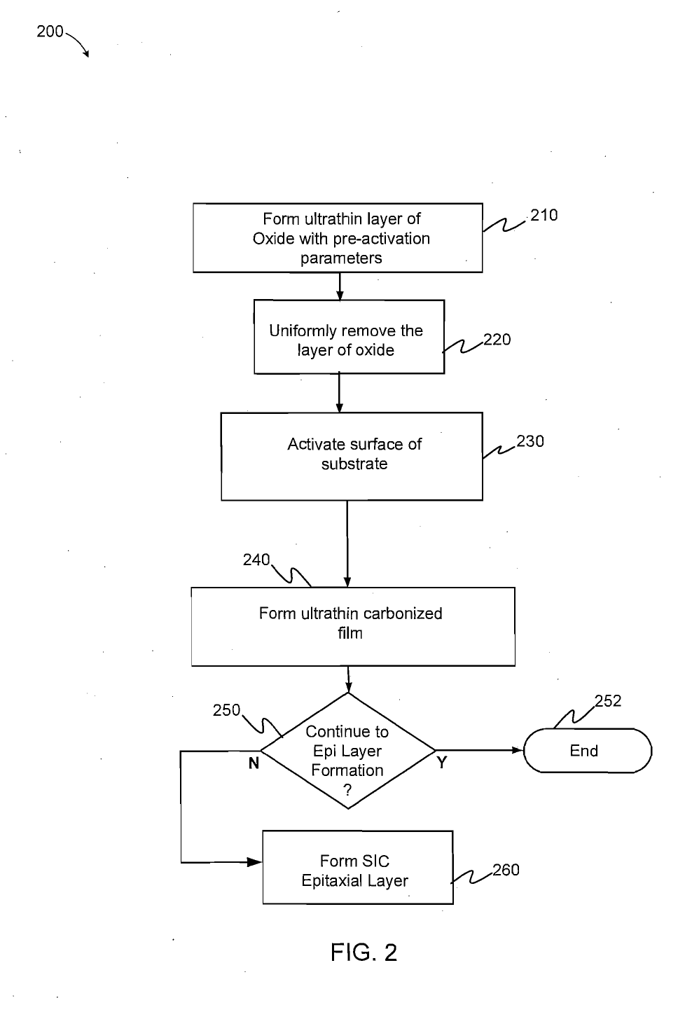

FIG. 2 is a flow diagram depicting an example of a process for preparing a surface of a substrate to facilitate silicon carbide deposition, according to at least some embodiments. In accordance with flow 200, an ultrathin oxide is formed and the surface of the substrate is activated from 210 to 230. In particular, the ultrathin oxide is formed under a first set of fabrication parameters at 210. In some embodiments, the first set of fabrication parameters include temperature values and pressure values that inhibit the interactions of carbon with a silicon substrate while promoting growth of an ultrathin SiO₂ layer. Further, the temperature can be modified from an initial temperature at 210 to an ending temperature at 220, during which the ultrathin SiO₂ layer is grown. At 220, the ultrathin SiO₂ layer is removed under, for example, a second set of fabrication parameters that promotes the removal of SiO₂. At 230, the surface of the substrate is activated in preparation for interacting with carbon to form, for example, a carbonized layer on the substrate.

At 240, a third set of fabrication parameters is used to form a carbonized layer (e.g., an ultrathin carbonized film) on the surface. As used herein, the term “ultrathin carbonized film” can refer, at least in some embodiments, to a structure that has a thickness ranging from one monolayer to multiple monolayers of carbonized silicon. In some examples, the ultrathin carbonized film is one to two atomic layers thick. Specifically, the ultrathin carbonized film can be less than 2 nm (e.g., less than 1 nm thick), at least in some instances. In some embodiments, the ultrathin carbonized film is a structure that inhibits interactions between silicon and carbon. For example, the ultrathin carbonized film can suppress such interactions as the temperature changes from a pre-activation temperature to a surface-activation temperature. Further, the ultrathin carbonized film can be formed at relatively low temperatures (e.g., lower than typical temperatures of 1,400° C.), which can enhance the quality of the crystal lattice of a subsequently formed silicon carbide epitaxial layer. In some embodiments, an ultrathin carbonized film is a “transitory film,” which is a structure formed to endure from the transition of one processing step to another processing step. At 250, flow 200 diverts either to 252 or to 260 as a function of whether an epitaxial layer of silicon carbide is to be formed (or any other structure, such as a seed epitaxial layer or a heterojunction interface layer as described, for example, in U.S. patent application Ser. No. 12/543,478). If so, then the fabrication parameters are changed, including a ramping of the temperature, and flow moves to 260. Otherwise, flow 200 ends at 252.

As used herein, the term “pre-activation temperature” can refer, at least in some embodiments, to a temperature below which silicon and carbon interact for a respective pressure, and the term “surface-activation temperature” can refer, at least in some embodiments, to a temperature at which silicon and carbon interact sufficiently to form an epitaxial layer of silicon carbide for a respective pressure, and/or the temperature at which to deposit silicon on the surface of the silicon substrate. Further, the ultrathin carbonized film can inhibit the partial interactions between silicon and carbon at a partial-activation temperature, which is less than the surface-activation temperature, but is relatively close to the surface-activation temperature. The partial-activation temperature can cause partial interactions that otherwise might facilitate undesirable silicon and carbon interactions as flow 200 moves, for example, from 240 to 260. As such, the ultrathin carbonized film can inhibit partial interactions between silicon and carbon, as well as between the silicon in the surface and any other element or molecule. For example, a wafer having an ultrathin carbonized file formed thereupon can suppress interactions between silicon in the surface and an ambient environment in which, for example, native oxide might otherwise grow. In some embodiments, flow 200 can be implemented using low pressure chemical vapor deposition (“LPCVD”) from 210 to 240.

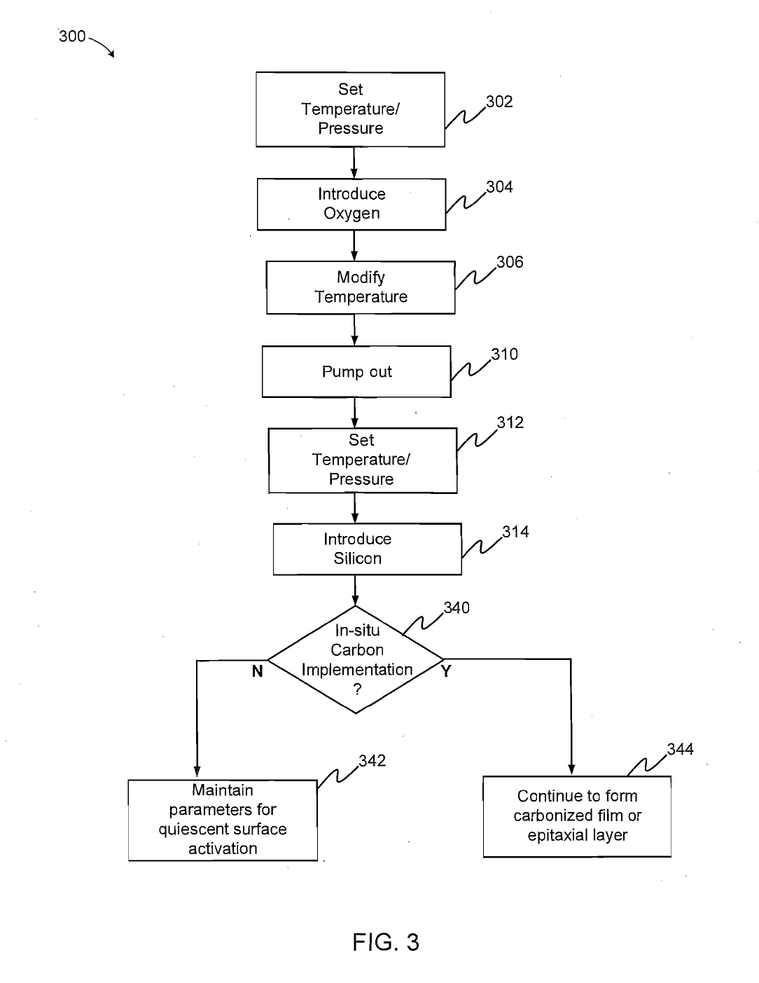

FIG. 3 is a flow diagram depicting an example of activating a substrate surface for silicon carbide deposition, according to various embodiments. At 302 of flow 300, the temperature and the pressure are set as initial fabrication parameters, among others (e.g., flow rates, etc.). In some embodiments, the temperature is set to an initial temperature, which is at or below a temperature at which silicon and carbon interacts (i.e., at or below a temperature at which carbon diffuses into the silicon substrate at a rate that produces undesirable structures). Further, the initial temperature can be set above another temperature at which oxide grows for a respective pressure, according to some embodiments. Therefore, the initial temperature can range from approximately 500° C. to approximately 670° C., or up to 750° C., according to various embodiments. In one or more embodiments, the pressure at 302 is set such the pressure (i.e., pressure or partial pressure) of oxygen is set relatively high to cause multiple collisions between oxygen and carbon contaminants at 304. For example, the pressure of oxygen can be set such that the mean free path of O₂ molecules is about 200 micrometers (“μm”), which, in turn, provides for multiple collisions between O₂ molecules and carbon contaminants. The collisions form stable carbon-based molecules, such as carbon dioxide (“CO₂”). Therefore, most or substantially all carbon atoms are inhibited from reaching the surface of the substrate during the introduction of oxygen at 304. In some embodiments, the initial pressure set at 302 can range from a pressure that provides for a mean free path of O₂ molecules of about 200 μm to any other relatively high pressure.

At 306, the temperature is ramped up from the initial temperature to an ending temperature that, for example, can be equivalent to the surface-activation temperature. The temperature is ramped at a rate to sufficiently grow an ultrathin SiO₂ layer having a thickness, for example, ranging between 1 nm and 2 nm, or greater, according to some embodiments. During 306, the ultrathin SiO₂ layer is formed to have a substantially uniform thickness. Contaminants and carbon-based molecules formed at 304 are then pumped out at 310. At 312, the temperature and the pressure are set to facilitate the removal of the ultrathin SiO₂ layer and the activation of the surface. For example, the ending temperature is set to surface-activation temperature, and the pressure is set to a relatively low pressure. In some embodiments, the pressure is set to the molecular flow regime (e.g., for silicon in a gaseous state, as a silicon precursor).

At 314, silicon is introduced and the ultrathin SiO₂ layer is removed in accordance with, for example, the following reaction: Si(g)+SiO₂(s)=>2SiO(g). Subsequent to the removal of the last portions of the ultrathin SiO₂ layer, silicon can be deposited onto the silicon substrate surface to form an activated surface. Accordingly, the activated surface can be free of stacking faults and also can have a continuously uniform surface. At 340 of flow 300, a determination is made as to whether further in-situ processing is to be performed, such as forming an ultrathin carbonized film. If processing is to continue, then flow 300 moves to 344 at which fabrication parameters are modified to facilitate the formation of the ultrathin carbonized film on top of the activated surface. Otherwise, flow 300 moves to 342 at which the fabrication parameters remain unchanged or are set to a state to provide for quiescent surface activation (i.e., the surface remains activated with, for example, available silicon bonds free to interact with carbon). For example, the activated surface can remain in a reaction region that maintains a relatively high vacuum (e.g., less than about 4×10⁻⁷ mbar of O₂ or H₂O). In some cases, the temperature can be reduced while the activated surface remains activated.

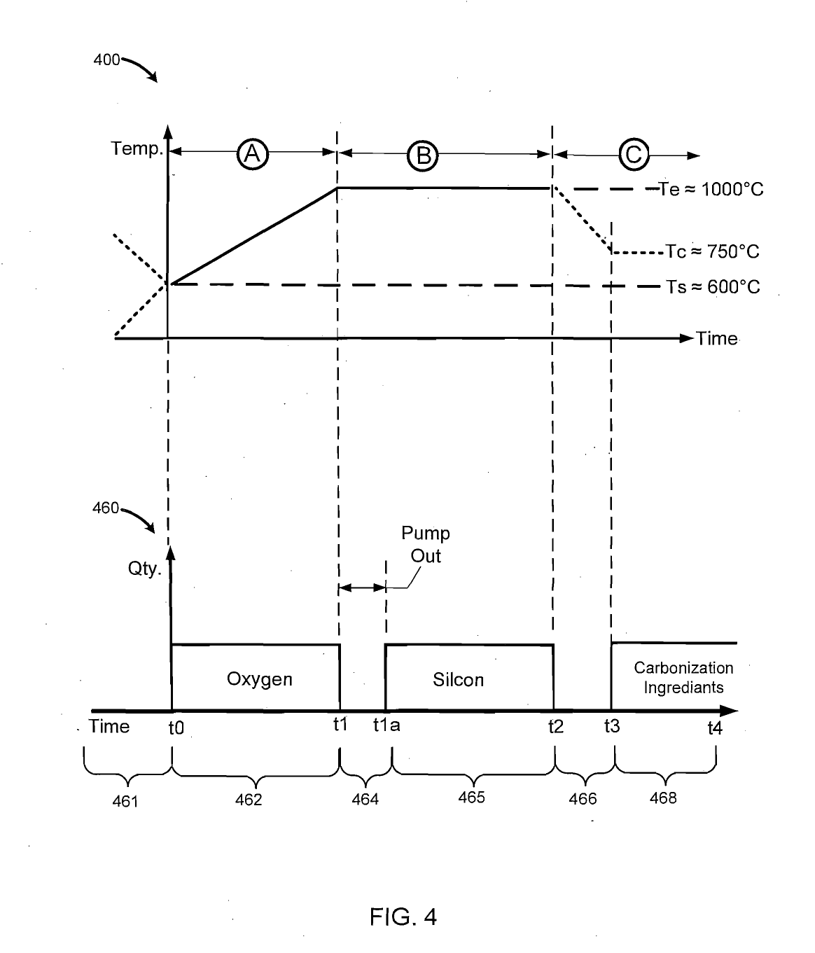

FIG. 4 is a diagram depicting an example of introducing materials during the formation of an ultrathin oxide and the activation of substrate surface, according to various embodiments. FIG. 4 depicts examples of temperature characteristics 400 over time and relative quantities (“Qty.”) 460 of materials used over time for fabricating an ultrathin oxide and activating a substrate surface. As shown in temperature characteristics 400, the temperature can be ramped from start temperature, Ts, to one or more ending temperatures, Te, which is the temperature at which the substrate surface is activated. In some embodiments, start temperature, Ts, can be described as the pre-activation temperature, and the start temperature can be within the range from about 500° C. to about 800° C. In other embodiments, the start temperature, Ts, can be any temperature, including an ambient temperature. In the example shown, the start temperature, Ts, is set to approximately 600° C. In some embodiments, ending temperature, Te, can be within the range from about 800° C. and 1,100° C. In one example, the ending temperature can be approximately 1,000° C. or 1,050° C., or any temperature in between such that the surface of the substrate is sufficiently activated. Therefore, the surface of the substrate and/or a reaction region (not shown) can be ramped from start temperature, Ts, to ending temperature, Te, at a rate of about 5° C./minute from time zero, t0, to time one, t1, during interval 462, according to some embodiments.

To illustrate the introduction of materials, consider that during interval 461 is a period of time representing the time prior to surface activation in which the temperature is modified (e.g., ramped up or down) to set the start temperature, Ts, as shown in interval 462. During interval 462, oxygen is introduced into, for example, a reaction region that includes the wafer, whereby the oxygen is a source of, for example, O₂ molecules. Interval 462 can be described as phase A, as denoted by encircled letter A, and can extend from time zero, t0, to time one, t1. In some embodiments, an oxygen source can be introduced at flow rates, for example, at approximately 18 standard cubic centimeters per minute (“sccm”) to approximately 22 sccm, but can be at other flow rates for a particular pressure. An example of a flow rate for interval 462 can be 20 sccm. In one embodiment, the pressure of oxygen is set to 0.3 mbar, or greater. In some embodiments, interval 462 can range from approximately ten minutes to approximately one-hundred twenty minutes based on, for example, the temperature ramp rate. For example, interval 462 can last for approximately 80 minutes (e.g., using a ramp rate of 5° C./minute from time zero, t0, to time one, t1).

Phase B, as denoted by encircled letter B, spans intervals 464 and 465. During interval 464, contaminants (e.g., carbon-based molecules) are pumped out from time one, t1, to time one-a, t1a. During interval 465, silicon is introduced to remove the ultrathin oxide formed in phase A. Examples of other fabrication parameters include a flow rate of 1.5 sccm for a silicon material (e.g., SiH₄) and at a pressure at around 2×10⁻⁴ mbar. Other silicon sources (other than SiH₄) can be used in other implementations. Examples of silicon sources include silicon-based gases, such as silane (“SiH₄”) and other gases having the form SiH_{X}. Other examples of silicon-based gases include silicon-based gases of the form SiHₓCl_{y}, or the form SiHₓCH_{z}. In still more examples, silicon sources can include mixtures of gases, including mixtures of silicon-based gases. One example of such a mixture includes silane (“SiH₄”) and tetrachlorosilane (“SiCl₄”). In some cases, interval 465 can last about 15 minutes between time one-a, t1a, to time two, t2, during which silicon is deposited on the surface to activate the substrate surface.

Phase C, as denoted by encircled letter C, spans intervals 466 and 468. During interval 466, the temperature of the activated surface is ramped down (e.g., with an optional pump out) from time two, t2, to time three, t3, to a carbonization temperature, Tc. An example of a ramp down rate is about 5° C./minute. In at least one embodiment, carbonization temperature, Tc, is approximately 750° C. During interval 468, the temperature of the activated surface is maintained from time three, t3, to time four, t4, at the carbonization temperature, Tc, as carbonization ingredients or materials are introduced to form an ultrathin carbonized film.

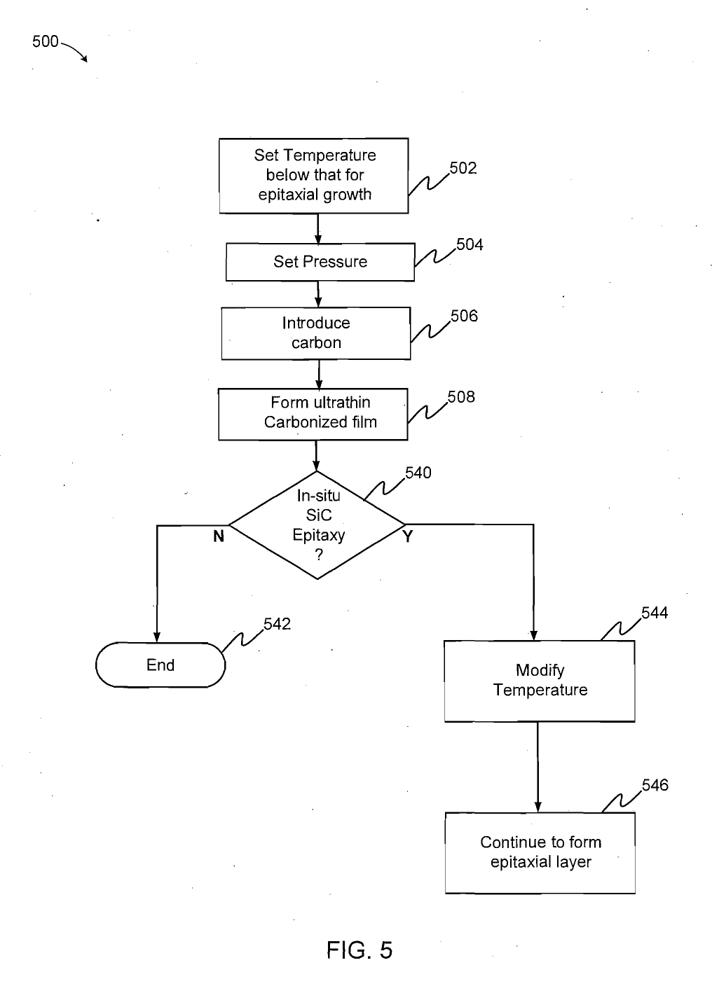

FIG. 5 is a flow diagram depicting an example of forming an ultrathin carbonized film, according to various embodiments. At 502 of flow 500, the temperature is set as a fabrication parameter, among others (e.g., pressure, flow rates, etc.). In some embodiments, the temperature is set to a carbonization temperature, which is at or below a temperature at which silicon and carbon interacts at sufficient rates to form an epitaxial layer of silicon carbide. For example, the carbonization temperature can be set to a temperature at which the diffusion of carbon into the silicon substrate is minimal or non-existent (e.g., for a particular pressure). The temperature can range from approximately 750° C. to approximately 800° C., or up to 950° C., according to various embodiments. In one or more embodiments, at 504, the pressure is set such the pressure (i.e., pressure or partial pressure) of carbon is set interact with the silicon bonds of an activated silicon substrate surface to form a uniformly (or substantially uniform) thin layer of carbonized silicon. At 506, carbon is introduced and the ultrathin carbonized film is formed at 508. At 540, a determination is made as to whether in-situ epitaxial silicon carbide layer formation is to be performed. If processing is to continue, then flow 500 moves to 544 at which fabrication parameters are modified (e.g., the temperature is changed from the carbonization temperature to the surface-activation temperature) to facilitate the formation of a silicon carbide epitaxial layer on top of or in place of the ultrathin carbonized film. Otherwise, flow 500 moves to 546 at which silicon carbide epitaxy is performed.

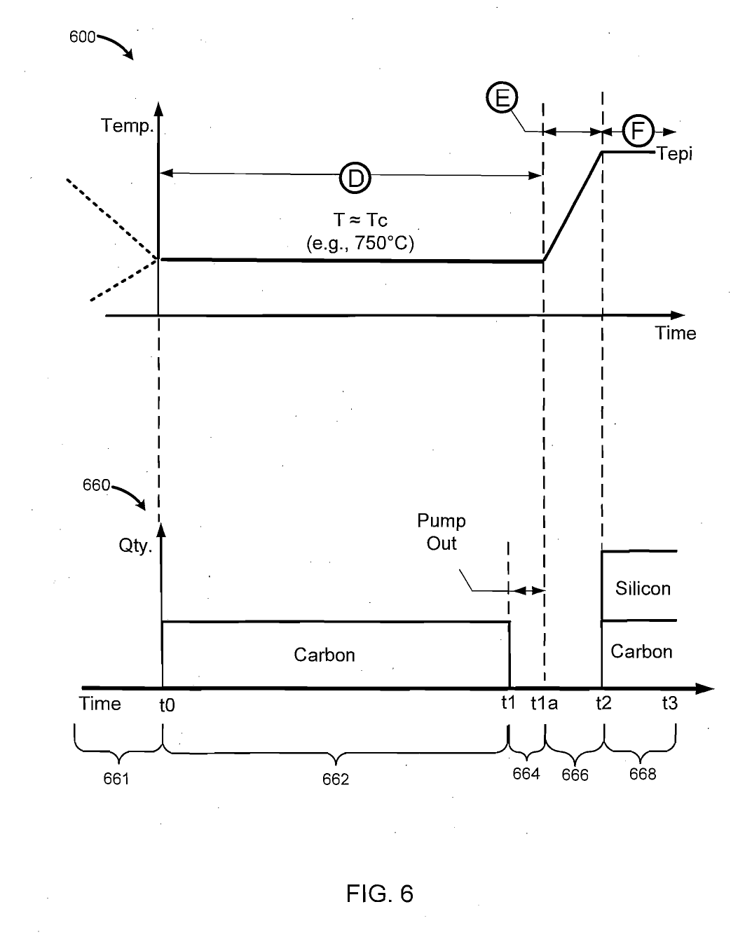

FIG. 6 is a diagram depicting an example of introducing materials during the formation of an ultrathin carbonized film, according to various embodiments. FIG. 6 depicts examples of temperature characteristics 600 over time and relative quantities (“Qty.”) 660 of materials used over time for fabricating an ultrathin carbonized film. As shown in temperature characteristics 600, the temperature is set to the carbonization temperature, Tc, which can range from approximately 700° C. to approximately 800° C., or up to 950° C. In the example shown, the carbonization temperature is approximately 750° C. Subsequent to the formation of the ultrathin carbonized film, the temperature can be ramped up to an epitaxial temperature, Tepi, at which a silicon carbide epitaxial layer can be formed.

To illustrate the introduction of materials, consider that during interval 661 is a period of time representing the time prior to surface activation in which the temperature is modified (e.g., ramped down from a surface activation process step, such as shown in FIG. 4 as time interval 466) to set the carbonization temperature, Tc, as shown in interval 662. During 662, carbon is introduced into, for example, a reaction region (not shown) that includes the wafer having an activated surface. Interval 662 can be described as phase D, as denoted by encircled letter D, and can extend from time zero, t0, to time one, t1, up through time one-a, t1a. Note that interval 662 can coincide with interval 468 of FIG. 4 in cases where the ultrathin carbonized film is formed in situ subsequent to the formation of the ultrathin oxide. In an alternate embodiment, the carbonization temperature can be ramped between an initial carbonization temperature at time zero, t0, to another carbonization temperature at time one, t1. For example, the carbonization temperature can be ramped from approximately 750° C. to approximately 800° C. at 5° C./minute.

In some embodiments, carbon material or source can be introduced at flow rates, for example, at approximately 5 standard cubic centimeters per minute (“sccm”) to approximately 10 sccm, or can be introduced at other flow rates for a respective pressure. An example of a flow rate for interval 662 can be 10 sccm. In one embodiment, the pressure of oxygen is set to 0.02 mbar, or less. In one example, the pressure (or partial pressure) can range from 0.007 mbar to 0.02 mbar. In yet another example, the pressure (or partial pressure) can be 0.0013 mbar. In one embodiment, the source of carbon is acetylene (e.g., C₂H₂), but can be any variant thereof having the form CₓHₓ, as well as any hydrocarbon compound having the forms C_{X}H_{2X}, CxH_{2X-2}, C_{X}H_{2X-1} and the like. In some embodiments, interval 662 can range from approximately 30 seconds to approximately 2 minutes. In one embodiment, interval 662 can span approximately one minute. During interval 664, a pump out operation can be performed. Phase E, as denoted by encircled letter E, spans interval 666. During interval 666, the temperature can be ramped to 1,000° C. at 5° C./minute in the presence of about 0.05 mbar of C₂H₂ (e.g., at a flow rate of 10 sccm) optionally mixed with H₂ (e.g., at a flow rate of 450 sccm). As such, high temperature ramp rates of, for example, 100° C./second can be avoided. Phase F, as denoted by encircled letter F, spans interval 668. During interval 668, the temperature is set to an epitaxial temperature, Tepi, at which a silicon carbide epitaxial layer can be formed. In one example, silicon sources and carbon sources can be introduce either concurrently or in an alternating manner from time two, t2, to time three, t3.

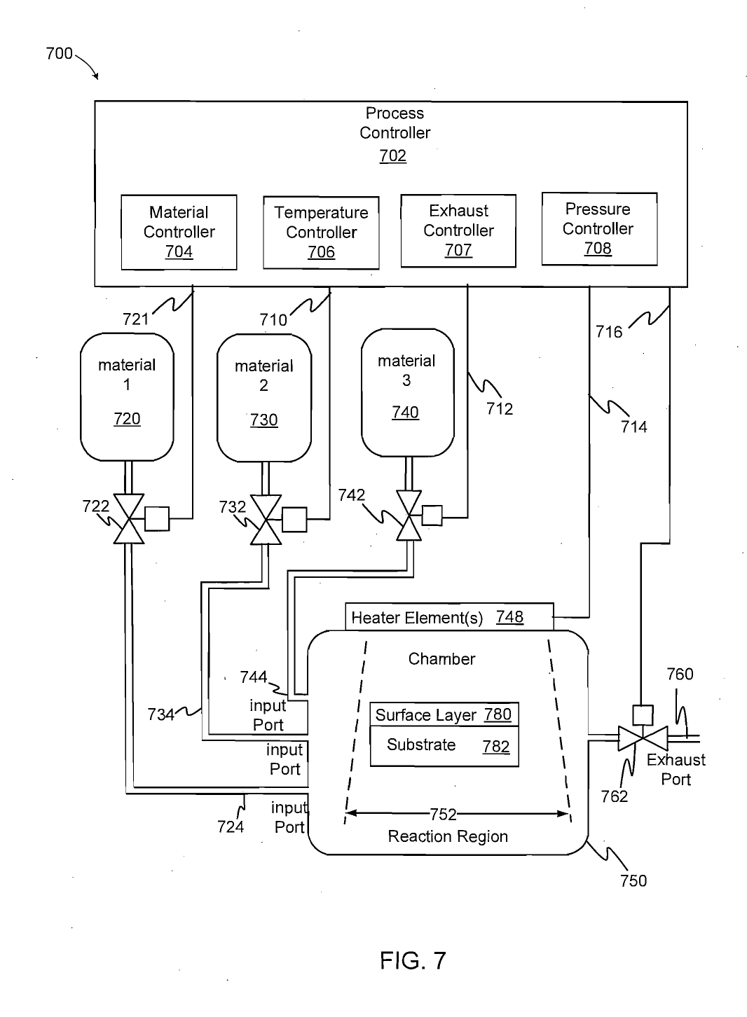

FIG. 7 illustrates a system implementing a process controller that is configured to form an ultrathin oxide, activate a substrate surface, and/or form an ultrathin carbonized film, according to some embodiments. System 700 can include a process controller 702, a reservoir 720 (e.g., a gas tank) of material 1, such as oxygen gas, a reservoir 730 (e.g., a gas tank) of material 2, such as silicon gas, a reservoir 740 (e.g., a gas tank) of material 3, such as carbon gas, a heater element or elements 748, and a chamber 750, which can be configured as a tube-like structure. Note that heater element 748 is depicted as a representative mechanism by which to heat substrate 782 and/or reaction region 752 by way of, for example, infrared heating, RF heating, etc. Thus, heater element 748 need not be configured to heat the walls of chamber 750, and, as such, the walls of chamber 750 can facilitate “cold wall” wafer processing, according to some embodiments. In some embodiments, however, heater element 748 can provide for “hot wall” wafer processing. As shown, a substrate 782 (with or without a surface layer) can be disposed in a reaction region 752 at which sources of silicon, carbon, and oxygen can be introduced to form an ultrathin oxide, an activated surface, and/or an ultrathin carbonized film as surface 780.

Process controller 702 can include a material controller 704, a temperature controller 706, an exhaust controller 707, and a pressure controller 708. Precursor controller 704 can be configured to control the introduction of the materials into chamber 750. For example, material controller 704 can transmit control signals via path 721 to control valve 722, which can open to provide oxygen as a material from reservoir 740 via input port 744 to reaction region 752. The oxygen can be used for form surface layer 780 as an ultrathin oxide. Similarly, during another interval of time, material controller 704 can transmit control signals via path 710 to control valve 732, which can open to provide silicon as a material from reservoir 730 via input port 734 to reaction region 752. The silicon can remove the ultrathin oxide and activate substrate 782 to form an activated surface as surface layer 780. Further, material controller 704 can transmit control signals via path 712 to control valve 742, which can open to provide carbon as a material from reservoir 740 via input port 744 to reaction region 752. The carbon can be used to form the ultrathin carbonized film.

Temperature controller 706 can be configured to transmit control signals via path 714 to one or more heater elements 748 to ramp up and down the temperatures, as well as to maintain various temperatures described herein. Exhaust controller 707 can be configured to transmit control signals via path 716 to control valve 762 to facilitate pumping out gaseous material or contaminants out through an exhaust port 760. In some embodiments, pressure controller 708 can be configured to maintain reaction region 752 at a relatively high vacuum to introduce materials in the molecular flow regime, and can reach relatively high pressures for introducing, for example, oxygen during formation of the ultrathin oxide. In some embodiments, a relatively high vacuum can be described by pressures (or approximate pressures) of 1×10⁻³ mbar or less, including pressures of 9×10⁻⁵ mbar (i.e., 0.00009 mbar) or less, and relatively high pressures can be described as pressures (or approximate pressures) of 0.3 mbar or greater.

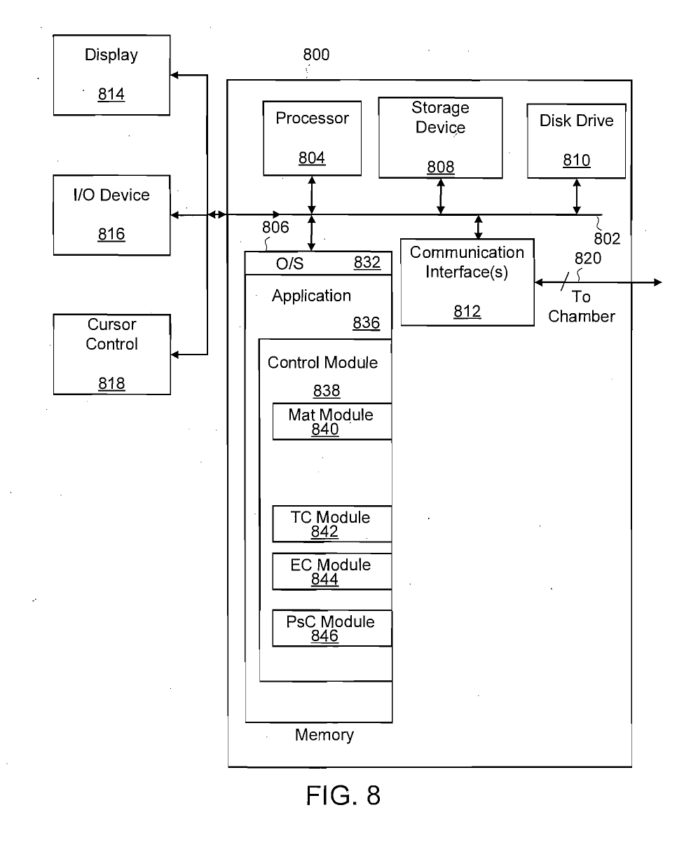

FIG. 8 illustrates an exemplary computer system suitable to form an ultrathin oxide, activate a substrate surface, and/or form an ultrathin carbonized film, according to at least one embodiment. In some examples, computer system 800 can be used to implement computer programs, applications, methods, processes, or other software to perform the above-described techniques and to realize the structures described herein. Computer system 800 includes a bus 802 or other communication mechanism for communicating information, which interconnects subsystems and devices, such as one or more processors 804, system memory (“memory”) 806, storage device 808 (e.g., ROM), disk drive 810 (e.g., magnetic or optical), communication interface 812 (e.g., a modem, Ethernet card, or any other interface configured to exchange data with a communications network or to control a fabrication machine), display 814 (e.g., CRT or LCD), input device 816 (e.g., keyboard), and pointer cursor control 818 (e.g., mouse or trackball). In one embodiment, pointer cursor control 818 invokes one or more specialized commands that can configure one or more of the following: the flow rates and the timing for the introduction of materials, the temperature characteristics (e.g., ramping up and ramping down temperatures, and maintaining a relatively quiescent temperature) during various phases of the formation of ultrathin oxide, surface activation, and/or the formation of an ultrathin carbonized film, the pressures for various phases, and/or the rate and the timing of pumping out a chamber, as well as other parameters that can influence the processes and sub-processes described herein.

According to some examples, computer system 800 performs specific operations in which processor 804 executes one or more sequences of one or more instructions stored in system memory 806. Such instructions can be read into system memory 806 from another computer readable medium, such as static storage device 808 or disk drive 810. In some examples, hard-wired circuitry can be used in place of or in combination with software instructions for implementation. In the example shown, system memory 806 includes modules of executable instructions for implementing an operation system (“O/S”) 832, an application 836, and an epitaxy control module 838, which, in turn, can implement a material controller (“Mat Module”) module 840, a temperature controller (“TC”) module 842, an exhaust controller (“EC”) module 844, and a pressure controller (“PsC”) module 846, each of which can provide functionalities described herein.

The term “computer readable medium” refers, at least in one embodiment, to any medium that participates in providing instructions to processor 804 for execution. Such a medium can take many forms, including but not limited to, non-volatile media, volatile media, and transmission media. Non-volatile media includes, for example, optical or magnetic disks, such as disk drive 810. Volatile media includes dynamic memory, such as system memory 806. Transmission media includes coaxial cables, copper wire, and fiber optics, including wires that comprise bus 802. Transmission media can also take the form of electromagnetic, acoustic or light waves, such as those generated during radio wave and infrared data communications.

Common forms of computer readable media includes, for example, floppy disk, flexible disk, hard disk, magnetic tape, any other magnetic medium, CD-ROM, any other optical medium, punch cards, paper tape, any other physical medium with patterns of holes, RAM, PROM, EPROM, FLASH-EPROM, any other memory chip or cartridge, time-dependent waveforms, or any other medium from which a computer can read instructions.

In some examples, execution of the sequences of instructions can be performed by a single computer system 800. According to some examples, two or more computer systems 800 coupled by communication link 820 (e.g., links to LAN, PSTN, or wireless network) can perform the sequence of instructions in coordination with one another. Computer system 800 can transmit and receive messages, data, and instructions, including program code (i.e., application code) through communication link 820 and communication interface 812. Received program code can be executed by processor 804 as it is received, and/or stored in disk drive 810, or other non-volatile storage for later execution. In one embodiment, system 800 (or a portion thereof) can be integrated into a furnace for performing various deposition techniques, such as variants of chemical vapor deposition (“CVD”), etc.

In at least some examples, the structures and/or functions of any of the above-described features can be implemented in software, hardware, firmware, circuitry, or a combination thereof. Note that the structures and constituent elements above, as well as their functionality, may be aggregated with one or more other structures or elements. Alternatively, the elements and their functionality may be subdivided into constituent sub-elements, if any. As software, the above-described techniques may be implemented using various types of programming or formatting languages, frameworks, syntax, applications, protocols, objects, or techniques. As hardware and/or firmware, the above-described techniques may be implemented using various types of programming or integrated circuit design languages, including hardware description languages, such as any register transfer language (“RTL”) configured to design field-programmable gate arrays (“FPGAs”), application-specific integrated circuits (“ASICs”), or any other type of integrated circuit. These can be varied and are not limited to the examples or descriptions provided.

The description, for purposes of explanation, uses specific nomenclature to provide a thorough understanding of the invention. However, it will be apparent that specific details are not required in order to practice the invention. In fact, this description should not be read to limit any feature or aspect of to any embodiment; rather features and aspects of one example can readily be interchanged with other examples. Notably, not every benefit described herein need be realized by each example of the invention; rather any specific example may provide one or more of the advantages discussed above. In the claims, elements and/or operations do not imply any particular order of operation, unless explicitly stated in the claims. It is intended that the following claims and their equivalents define the scope of the invention.

What is claimed:

1. A method of preparing a substrate for silicon carbide epitaxial layer formation, the method comprising:
forming an ultrathin layer of oxide that is configured to inhibit contaminants from interacting with a silicon-based substrate; and
forming a carbonized film on the silicon-based substrate that is configured to inhibit contaminants from interacting with the silicon-based substrate as fabrication parameters are modified to form an epitaxial layer of silicon carbide.

2. The method of claim 1 wherein forming the ultrathin layer of oxide and the carbonized film comprises:
implementing a low pressure chemical vapor deposition (“LPCVD”) process,
wherein the fabrication parameters include temperature and pressure.

3. The method of claim 1 wherein the contaminants comprise carbon elements as a contaminant.

4. The method of claim 1 further comprising:
modifying a temperature of a reaction region in which the ultrathin layer of oxide is grown to a surface-activation temperature,
wherein the ultrathin layer of oxide inhibits a contaminant from interacting with the silicon-based substrate during the temperature modification.

5. The method of claim 4 wherein modifying the temperature comprises:
starting the temperature at an initial temperature, and
ending the temperature at the surface-activation temperature.

6. The method of claim 4 further comprising:
introducing oxygen into the reaction region, and
setting the pressure of the reaction region into which the oxygen is introduced above a pressure to inhibit carbon elements as one of the contaminants from interacting with the silicon-based substrate.

7. The method of claim 1 further comprising:
activating the surface of the silicon-based substrate.

8. The method of claim 7 further comprising:
introducing silicon elements into a reaction region in which the ultrathin layer of oxide resides; and
setting the pressure of the reaction region into which the silicon elements are introduced at a low pressure.

9. The method of claim 8 wherein the low pressure comprises:
setting pressure values indicative of a molecular-flow regime.

10. The method of claim 1 wherein forming a carbonized film comprises:
setting the temperature of a reaction region including the silicon-based substrate to a carbonization temperature; and
introducing carbon elements.

11. The method of claim 10 wherein setting the temperature of the reaction region comprises:
modifying the temperature from a surface-activation temperature to the carbonization temperature,
wherein the carbonization temperature is less than the surface-activation temperature.

12. The method of claim 10 wherein forming the carbonized film comprises:
forming multiple monolayers of silicon carbide.

13. The method of claim 10 wherein forming the carbonized film comprises:
forming a monolayer of silicon carbide.

14. A base wafer formed in accordance with the method of claim 12.

15. A method comprising:
setting the temperature of a reaction region including a substrate to a first temperature;
introducing oxygen elements into the reaction region at a first pressure;
ramping the temperature to a second temperature during the introduction of the oxygen;
activating the substrate at the second temperature; and
forming a carbonized film on the substrate at a third temperature.

16. The method of claim 15 wherein activating the substrate comprises:
introducing a silicon-based gas to remove an oxide layer formed during the introduction of the oxygen elements.

17. The method of claim 16 wherein introducing the silicon-based gas comprises:
introducing silane (“SiH₄”).

18. The method of claim 15 wherein forming the carbonized film comprises:
setting the third temperature between to temperatures between 700° C. and 850° C.

19. The method of claim 15 wherein forming the carbonized film comprises:
introducing a carbon-based gas to form the carbonized film.

20. The method of claim 19 wherein the carbon-based gas comprises:
acetylene (“C₂H₂”).

21. A base wafer formed in accordance with the method of claim 15.

22. A computer readable medium including executable instructions configured to:
set the temperature of a reaction region including a substrate to a first temperature;
introduce oxygen elements into the reaction region at a first pressure;
ramp the temperature to a second temperature during the introduction of the oxygen;
activate the substrate at the second temperature; and
form a carbonized film on the substrate at a third temperature.

23. The computer readable medium of claim 22 wherein the executable instructions configured to activate the substrate comprise executable instructions configured to:
introduce a silicon-based gas to remove an oxide layer formed during the introduction of the oxygen elements.

24. The computer readable medium of claim 23 wherein the executable instructions configured to introduce the silicon-based gas comprise executable instructions configured to:
introduce silane (“SiH₄”).

25. The computer readable medium of claim 22 wherein the executable instructions configured to form the carbonized film comprises executable instructions configured to:
set the third temperature between to temperatures between 700° C. and 850° C.

26. The computer readable medium of claim 22 wherein the executable instructions configured to form the carbonized film comprise executable instructions configured to:
introduce a carbon-based gas to form the carbonized film.

27. The computer readable medium of claim 26 wherein the executable instructions configured to introduce the carbon-based gas comprises executable instructions configured to:
introduce acetylene (“C₂H₂”).

28. A semiconductor wafer comprising:
a substrate including a bulk material; and
a carbonized film constituting a monocrystalline epitaxial layer comprising:
a carbonized layer of silicon.

29. The semiconductor wafer of claim 28 wherein the carbonized film comprises:
multiple monolayers of silicon carbide.

30. The semiconductor wafer of claim 28 wherein the carbonized film comprises:
a monolayer of silicon carbide.

31. The semiconductor wafer of claim 28 wherein the carbonized film comprises:
a material including silicon carbide.

32. The semiconductor wafer of claim 31 wherein the material has a thickness less than 2 nm.

33. The semiconductor wafer of claim 28 formed in accordance with a method comprising:
forming an ultrathin layer of oxide that is configured to inhibit contaminants from interacting with a silicon-based substrate; and
forming a carbonized film on the silicon-based substrate that is configured to inhibit contaminants from interacting with the silicon-based substrate as fabrication parameters are modified to form an epitaxial layer of silicon carbide.
